(19) United States
(12) Patent Application Publication
(10) Pub. No.: US 2024/0347492 A1
(43) Pub. Date: Oct. 17, 2024

(54) SEMICONDUCTOR DEVICE

(71) Applicant: Mitsubishi Electric Corporation, Tokyo (JP)

(72) Inventor: Shin CHAKI, Tokyo (JP)

(73) Assignee: Mitsubishi Electric Corporation, Tokyo (JP)

(21) Appl. No.: 18/343,490

(22) Filed: Jun. 28, 2023

(30) Foreign Application Priority Data
Apr. 11, 2023 (JP) 2023-064244

(51) Int. Cl. H01L 23/00; H01L 21/66; H01L 23/29; H01L 23/31; H01L 23/367; H01L 23/498

(52) U.S. Cl. CPC H01L 24/16; H01L 22/32; H01L 23/293; H01L 23/3107; H01L 23/367; H01L 23/49822; H01L 24/32; H01L 24/73; H01L 2224/16238; H01L 2224/32221; H01L 2224/73253; H01L 2924/384

(57) ABSTRACT

A semiconductor device includes: a multi-layer substrate; and a semiconductor chip mounted on the multi-layer substrate by flip-chip mounting and having an internal circuit, wherein plural pads are formed on a front surface of the semiconductor chip, plural pillars are respectively formed on the plural pads, plural upper-surface electrodes are formed on an upper surface of the multi-layer substrate, plural lower-surface electrodes are formed on a lower surface of the multi-layer substrate and are respectively connected with the plural upper-surface electrodes via through holes, the plural pillars are joined to the plural upper-surface electrodes by solder, the plural pads include an electrode pad connected with the internal circuit and plural inspection pads formed in at least three parts in four corners on the front surface of the semiconductor chip and not connected with the internal circuit, and a line connects the adjacent inspection pads with each other.

### BACKGROUND OF THE INVENTION

### Field

The present disclosure relates to a semiconductor device.

### Background

A semiconductor device has been used in which a semiconductor chip is mounted by flip-chip mounting (for example, see Patent Literature 1). In a case where a semiconductor chip is mounted on a multi-layer substrate, a pillar is formed on an electrode of the semiconductor chip, the semiconductor chip is flipped over, and the semiconductor chip is mounted on the multi-layer substrate while the electrode of the multi-layer substrate is caused to contact with the pillar of the semiconductor chip by solder. A heat sink is die-bonded to a back surface of the semiconductor chip. After those are sealed by mold-sealing, the heat sink is exposed by a procedure such as wafer backgrinding.

### CITATION LIST

### Patent Literature

Patent Literature 1: JP H11-026642 A

### SUMMARY

### Technical Problem

There may be a case where a semiconductor chip is inclined in flip-chip mounting. Further, there may also be a case where the semiconductor chip is inclined due to a fluid pressure in mold-sealing, a transverse stress in wafer backgrinding, an irresistible accident occurring in operation as a product, and so forth. There have been a case where the semiconductor chip is inclined, contact is not normally achieved between an electrode of a multi-layer substrate and a pillar of the semiconductor chip, and an opening condition of those occurs. Further, there have been a case where the pillar comes off from an electrode of the semiconductor or a contact defect occurs due to insufficient solder or the like.

The present disclosure has been made for solving the above-described problems, and an object thereof is to obtain a semiconductor device that can detect a contact defect between a multi-layer substrate and a semiconductor chip in a non-destructive manner.

### Solution to Problem

A semiconductor device according to the present disclosure includes: a multi-layer substrate; and a semiconductor chip mounted on the multi-layer substrate by flip-chip mounting and having an internal circuit, wherein plural pads are formed on a front surface of the semiconductor chip, plural pillars are respectively formed on the plural pads, plural upper-surface electrodes are formed on an upper surface of the multi-layer substrate, plural lower-surface electrodes are formed on a lower surface of the multi-layer substrate and are respectively connected with the plural upper-surface electrodes via through holes, the plural pillars are joined to the plural upper-surface electrodes by solder, the plural pads include an electrode pad connected with the internal circuit and plural inspection pads formed in at least three parts in four corners on the front surface of the semiconductor chip and not connected with the internal circuit, and a line connects the adjacent inspection pads with each other.

### Advantageous Effects of Invention

In the present disclosure, the inspection pads are formed in at least three parts in four corners on the front surface of the semiconductor chip and the adjacent inspection pads are connected with each other by the lines. A check is made to a contacting part of each of the inspection pads. In a case where short-circuits are occurring in all of the contacting parts, it can be determined that the semiconductor chip is evenly mounted. In this case, it can be determined that the electrode pads are also in contact. Thus, a contact defect between the multi-layer substrate and the semiconductor chip can be detected in a non-destructive manner.

### BRIEF DESCRIPTION OF DRAWINGS

FIG. 1 is a cross-sectional view illustrating a semiconductor device according to a first embodiment.

FIG. 2 is a cross-sectional view illustrating a state where the semiconductor chip is mounted while being inclined.

FIG. 3 is a diagram illustrating the front surface of the semiconductor chip according to the first embodiment.

FIG. 4 is a cross-sectional view illustrating a state where the semiconductor chip according to the first embodiment is mounted on the multi-layer substrate by flip-chip mounting.

FIG. 5 is a cross-sectional view illustrating a state where the semiconductor chip according to the first embodiment is mounted on the multi-layer substrate by flip-chip mounting.

FIG. 6 is a diagram illustrating a front surface of a semiconductor chip according to a second embodiment.

FIG. 7 is a cross-sectional view illustrating a state where the semiconductor chip according to the second embodiment is mounted on a multi-layer substrate by flip-chip mounting.

FIG. 8 is a diagram illustrating a front surface of a semiconductor chip according to a third embodiment.

FIG. 9 is a cross-sectional view illustrating a state where the semiconductor chip according to the third embodiment is mounted on a multi-layer substrate by flip-chip mounting.

FIG. 10 is a diagram illustrating a front surface of a semiconductor chip according to a fourth embodiment.

FIG. 11 is a diagram illustrating a front surface of a semiconductor chip according to a fifth embodiment.

FIG. 12 is a plan view illustrating a semiconductor device according to the fifth embodiment.

FIG. 13 is a diagram illustrating a front surface of a semiconductor chip according to a sixth embodiment.

FIG. 14 is a cross-sectional view illustrating a state where the semiconductor chip according to the sixth embodiment is mounted on a multi-layer substrate by flip-chip mounting.

FIG. 15 is a diagram illustrating results of one-port S-parameter measurement of a semiconductor device according to the sixth embodiment.

FIG. 16 is a diagram illustrating the measurement 1 of the semiconductor device according to the sixth embodiment.

FIG. 17 is a diagram illustrating the measurement 1 of the semiconductor device according to the sixth embodiment.

FIG. 18 is a diagram illustrating measurement according to a comparative example.

FIG. 19 is a diagram illustrating the measurement 3 of the semiconductor device according to the sixth embodiment.

FIG. 20 is a diagram illustrating a front surface of a semiconductor chip according to a seventh embodiment.

FIG. 21 is a diagram illustrating an upper surface of a multi-layer substrate according to the seventh embodiment.

FIG. 22 is a cross-sectional view illustrating a state where the semiconductor chip according to the seventh embodiment is mounted on the multi-layer substrate by flip-chip mounting.

FIG. 23 is a diagram illustrating a front surface of a semiconductor chip according to an eighth embodiment.

FIG. 24 is a diagram illustrating an upper surface of a multi-layer substrate according to the eighth embodiment.

FIG. 25 is a cross-sectional view illustrating a state where the semiconductor chip according to the eighth embodiment is mounted on the multi-layer substrate by flip-chip mounting.

### DESCRIPTION OF EMBODIMENTS

A semiconductor device according to the embodiments of the present disclosure will be described with reference to the drawings. The same components will be denoted by the same symbols, and the repeated description thereof may be omitted.

### First Embodiment

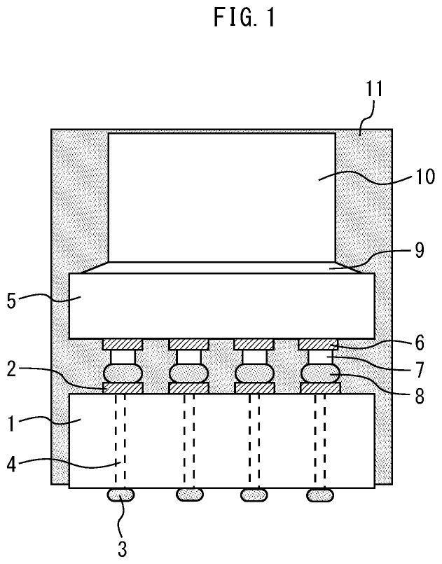

FIG. 1 is a cross-sectional view illustrating a semiconductor device according to a first embodiment. Plural upper-surface electrodes 2 are formed on an upper surface of a multi-layer substrate 1. Plural lower-surface electrodes 3 are formed on a lower surface of the multi-layer substrate 1 and are respectively connected with the upper-surface electrodes 2 via through holes 4 passing through the multi-layer substrate 1 in an up-down direction. A semiconductor chip 5 is mounted on the upper surface side of the multi-layer substrate 1 by flip-chip mounting. The semiconductor chip 5 serves as an amplifier monolithic microwave integrated circuit (MMIC). Plural pads 6 are formed on a front surface of the semiconductor chip 5. Pillars 7 are respectively formed on the plural pads 6. The plural pillars 7 of the semiconductor chip 5, which is flipped over, are respectively and individually joined to the plural upper-surface electrodes 2 of the multi-layer substrate 1 by solder 8.

A heat sink 10 is die-bonded to a back surface of the semiconductor chip 5 by using an adhesive 9 such as a conductive resin. The multi-layer substrate 1, the semiconductor chip 5, and the heat sink 10 are sealed by a mold resin 11. An upper surface of the heat sink 10 is exposed from the mold resin 11 by a procedure such as wafer backgrinding. Heat produced in the semiconductor chip 5 is dissipated from the upper surface side of the heat sink 10. The lower-surface electrodes 3 of the multi-layer substrate 1 are exposed from the mold resin 11 and are used for inputs and outputs of signals with respect to an external portion.

As for such a molded product, an external appearance of the semiconductor chip 5 mounted by flip-chip mounting cannot be seen. Thus, a time might be needed for investigation of causes and decision about measures when a characteristic defect occurs. For a quick investigation of causes, it is important to distinguish a defect mode due to a circuit from a defect mode due to assembly. An example of a representative mode of a defect due to assembly is a contact defect between the upper-surface electrode 2 of the multi-layer substrate 1 and the pillar 7 of the semiconductor chip 5.

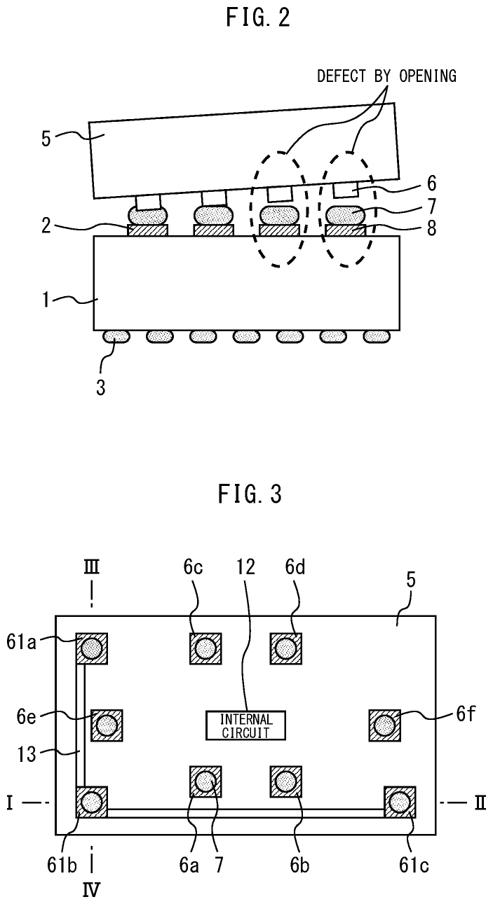

There may be a case where when flip-flop mounting is performed, the semiconductor chip 5 is mounted while being inclined due to a fluid pressure in mold-sealing, a transverse stress in wafer backgrinding, an irresistible accident occurring in operation as a product, and so forth. FIG. 2 is a cross-sectional view illustrating a state where the semiconductor chip is mounted while being inclined. In this case, defects by openings occur between the upper-surface electrodes 2 of the multi-layer substrate 1 and the pillars 7 of the semiconductor chip 5. Further, a contact defect might occur due to insufficient solder or the like, and the pillars 7 might come off from the pads 6 of the semiconductor chip 5. Realization of a procedure for detecting those contact defects in a non-destructive manner represents one of important techniques in production of molded products in which the semiconductor chips 5 are mounted by flip-chip mounting.

FIG. 3 is a diagram illustrating the front surface of the semiconductor chip according to the first embodiment. The semiconductor chip 5 has an internal circuit 12. On the front surface of the semiconductor chip 5, as the pads 6, electrode pads 6a to 6f and inspection pads 61a to 61c are formed. The electrode pads 6a to 6f are DC supplying pads or RF electrode pads which are connected with the internal circuit 12. The inspection pads 61a to 61c are formed in three parts in four corners on the rectangular front surface of the semiconductor chip 5 and are not connected with the internal circuit 12 of the semiconductor chip 5. Lines 13 are formed along two sides of the semiconductor chip 5. The line 13 formed along a short side of the semiconductor chip 5 connects the adjacent inspection pads 61a and 61b with each other. The line 13 formed along a long side of the semiconductor chip 5 connects the adjacent inspection pads 61b and 61c with each other.

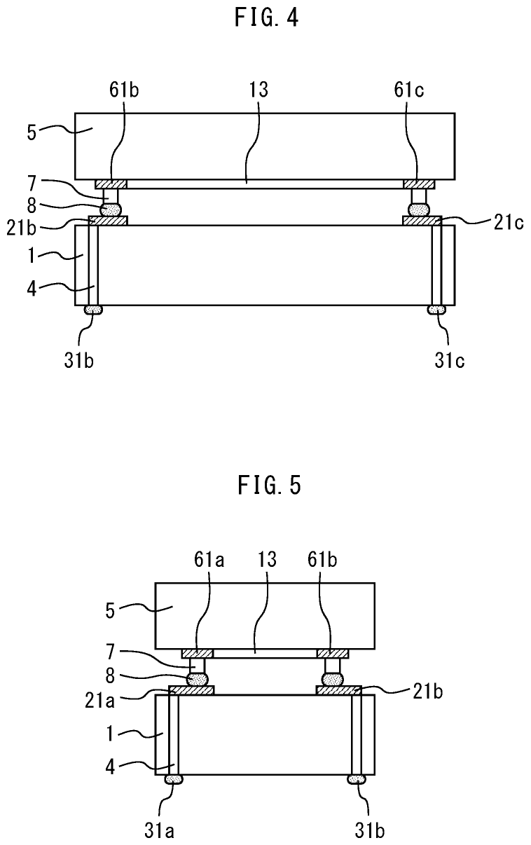

FIG. 4 and FIG. 5 are cross-sectional views illustrating a state where the semiconductor chip according to the first embodiment is mounted on the multi-layer substrate by flip-chip mounting. FIG. 4 corresponds to a cross-sectional view along a line I-II in FIG. 3. FIG. 5 corresponds to a cross-sectional view along a line III-IV in FIG. 3.

On the upper surface of the multi-layer substrate 1, as the upper-surface electrodes 2, upper-surface electrodes 21a, 21b, and 21c are formed. On the lower surface of the multi-layer substrate 1, as the lower-surface electrodes 3, lower-surface electrodes 31a, 31b, and 31c are formed and are respectively connected with the upper-surface electrodes 21a, 21b, and 21c via the through holes 4 passing through the multi-layer substrate 1 in the up-down direction. The pillars 7 formed on the inspection pads 61a to 61c are respectively and individually connected with the upper-surface electrodes 21a, 21b, and 21c by the solder 8.

Each of a resistance value between the lower-surface electrodes 31a and 31b, a resistance value between the lower-surface electrodes 31b and 31c, and a resistance value between the lower-surface electrodes 31c and 31a is measured, and a check is made about whether an opening (open) or a short-circuit (short) is occurring to a contacting part of each of the inspection pads (open-short check). In a case where the resistance value is sufficiently low, it is assessed that a short-circuit is occurring. In a case where short-circuits are occurring in all of the contacting parts, it can be determined that the semiconductor chip 5 is evenly mounted. In this case, it can be determined that the electrode pads 6a to 6f are also in contact. Thus, a contact defect between the multi-layer substrate 1 and the semiconductor chip 5 can be detected in a non-destructive manner.

### Second Embodiment

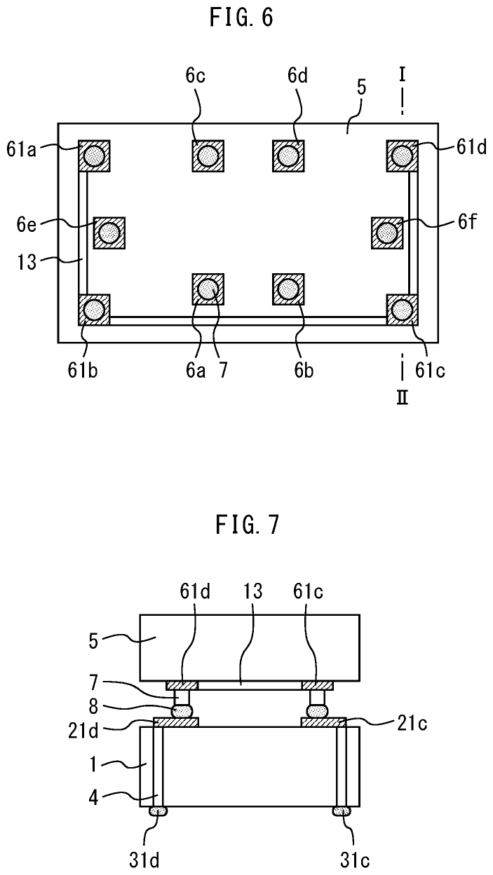

FIG. 6 is a diagram illustrating a front surface of a semiconductor chip according to a second embodiment. FIG. 7 is a cross-sectional view illustrating a state where the semiconductor chip according to the second embodiment is mounted on a multi-layer substrate by flip-chip mounting. FIG. 7 corresponds to a cross-sectional view along a line I-II in FIG. 6. Inspection pads 61a to 61d are formed in four corners of the semiconductor chip 5. The inspection pads 61a to 61d are not connected with the internal circuit 12 of the semiconductor chip 5. Lines 13 are formed along three sides of the semiconductor chip 5. The line 13 connects the inspection pads 61c and 61d together. An upper-surface electrodes 21d is connected with a lower-surface electrode 31d on the lower surface of the multi-layer substrate 1 via a through hole 4. The pillar 7 formed on the inspection pad 61d is connected with the upper-surface electrode 21d of the multi-layer substrate 1 by the solder 8. Other configurations are similar to those of the first embodiment.

In a case where a thickness of the semiconductor chip 5 is 50 μm or smaller, the chip might be warped in a protruded shape when the front surface of the chip is up. In such a case, when the front and back surfaces are inverted, contact checks about three parts in the four corners of the semiconductor chip 5 are not sufficient, but contact checks about four parts are necessary.

For example, the open-short check is performed for the condition between the lower-surface electrodes 31b and 31c. In a case of a short-circuit, it can be determined that the pillars 7 of the electrode pads 6a and 6b arranged between the inspection pads 61b and 61c are in contact with the upper-surface electrodes 2 of the multi-layer substrate 1. Similarly, the open-short check is performed for the condition between the lower-surface electrodes 31a and 31b. In a case of a short-circuit, it can be determined that the pillar 7 of the electrode pad 6e arranged between the inspection pads 61a and 61b is in contact with the upper-surface electrode 2 of the multi-layer substrate 1. The open-short check is performed for the condition between the lower-surface electrodes 31c and 31d. In a case of a short-circuit, it can be determined that the pillar 7 of the electrode pad 6f arranged between the inspection pads 61c and 61d is in contact with the upper-surface electrode 2 of the multi-layer substrate 1.

### Third Embodiment

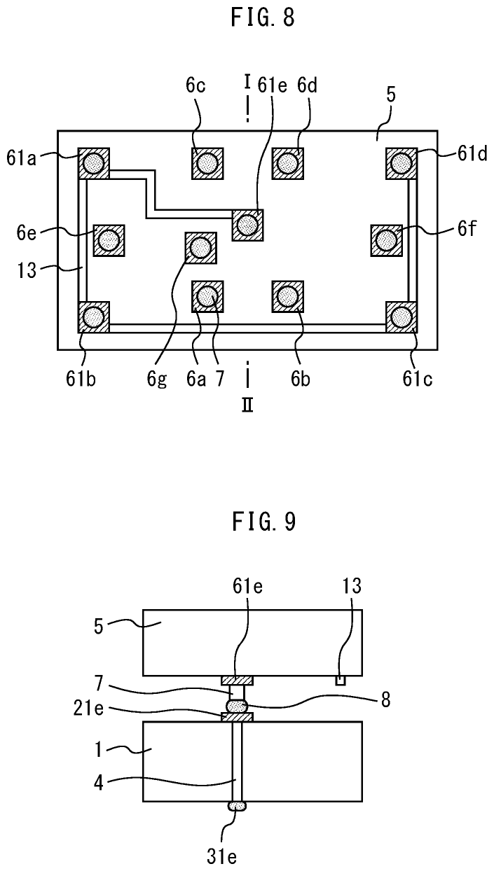

FIG. 8 is a diagram illustrating a front surface of a semiconductor chip according to a third embodiment. FIG. 9 is a cross-sectional view illustrating a state where the semiconductor chip according to the third embodiment is mounted on a multi-layer substrate by flip-chip mounting. FIG. 9 corresponds to a cross-sectional view along a line I-II in FIG. 8.

An inspection pad 61e is formed in a central portion of the front surface of the semiconductor chip 5 and is connected with the inspection pad 61a by the line 13. The inspection pad 61e is not connected with the internal circuit 12 of the semiconductor chip 5. An upper-surface electrode 21e is connected with a lower-surface electrode 31e on the lower surface of the multi-layer substrate 1 via the through hole 4. The pillar 7 formed on the inspection pad 61e is connected with the upper-surface electrode 21e by the solder 8. Other configurations are similar to those of the second embodiment.

In a case where the thickness of the semiconductor chip 5 is 50 μm or smaller, the chip might be warped in a recessed shape when the front surface of the chip is up. In such a case, when the front and back surfaces are inverted, contact checks about the four corners of the semiconductor chip 5 are not sufficient, but a contact check about the central portion of the chip is necessary as well. For example, the open-short check is performed for the condition between the lower-surface electrodes 31a and 31e. In a case of a short-circuit, it can be determined that the pillar 7 of an electrode pad 6g arranged around the inspection pad 61e is in contact with the upper-surface electrode 2 of the multi-layer substrate 1.

### Fourth Embodiment

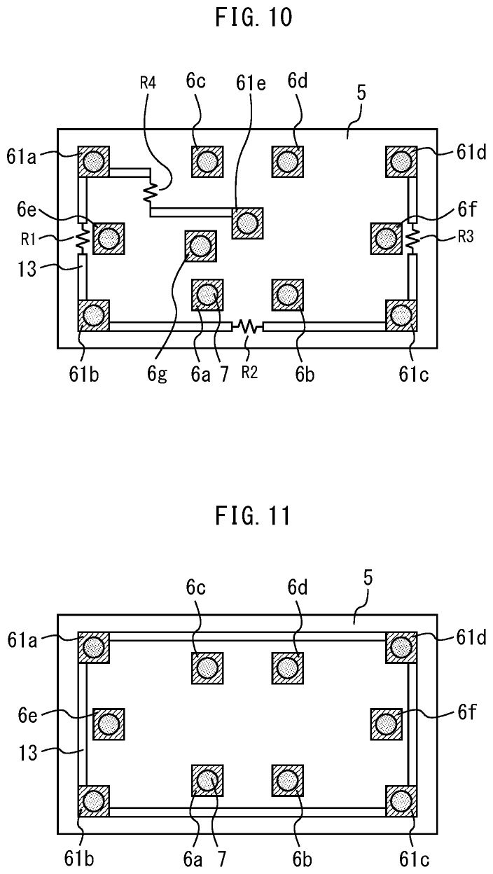

FIG. 10 is a diagram illustrating a front surface of a semiconductor chip according to a fourth embodiment. A resistance R1 is connected between the adjacent inspection pads 61a and 61b. A resistance R2 is connected between the adjacent inspection pads 61b and 61c. A resistance R3 is connected between the adjacent inspection pads 61c and 61d. A resistance R4 is connected between the adjacent inspection pads 61a and 61e. The resistance value of each of the resistances R1 to R4 is 10Ω, for example. For checking contact performance, the resistance is measured between each of the pads. In a case where the resistance value is another value than 10, 20, 30, or 40Ω, it can be determined that a contact defect is present. Other configurations and effects are similar to those of the third embodiment.

### Fifth Embodiment

FIG. 11 is a diagram illustrating a front surface of a semiconductor chip according to a fifth embodiment. The lines 13 also connect the inspection pads 61a and 61d together and are formed along an outer circumference of the front surface of the semiconductor chip 5.

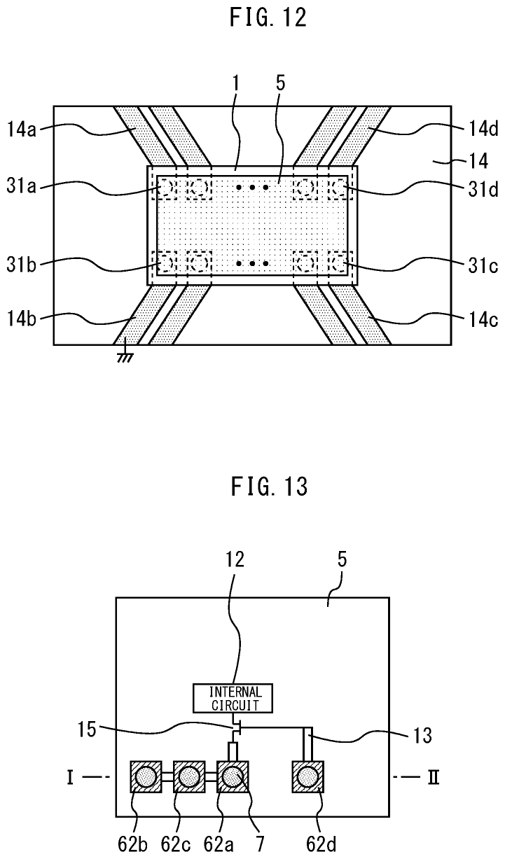

FIG. 12 is a plan view illustrating a semiconductor device according to the fifth embodiment. The multi-layer substrate 1 is mounted on a printed substrate 14. The lower-surface electrodes 31a to 31d for inspection are respectively connected with terminals 14a to 14d of the printed substrate 14. The terminal 14b is a GND terminal. Accordingly, GND connection is performed for the lines 13 formed along the outer circumference of the front surface of the semiconductor chip 5. Consequently, a guard ring is formed in the semiconductor chip 5, and an improvement in humidity resistance can thereby be intended.

### Sixth Embodiment

FIG. 13 is a diagram illustrating a front surface of a semiconductor chip according to a sixth embodiment. The semiconductor chip 5 has the internal circuit 12 and a transistor 15. On the front surface of the semiconductor chip 5, as the pads 6, an electrode pad 62a, inspection pads 62b and 62c, and a control pad 62d are formed. A source electrode and a drain electrode of the transistor 15 are respectively connected with the electrode pad 62a and the internal circuit 12. That is, the electrode pad 62a is connected with the internal circuit 12 via the transistor 15. The inspection pads 62b and 62c are connected with the electrode pad 62a by the respective lines 13. The control pad 62d is connected with a gate electrode as a control terminal of the transistor 15. The pillars 7 are respectively formed on those pads.

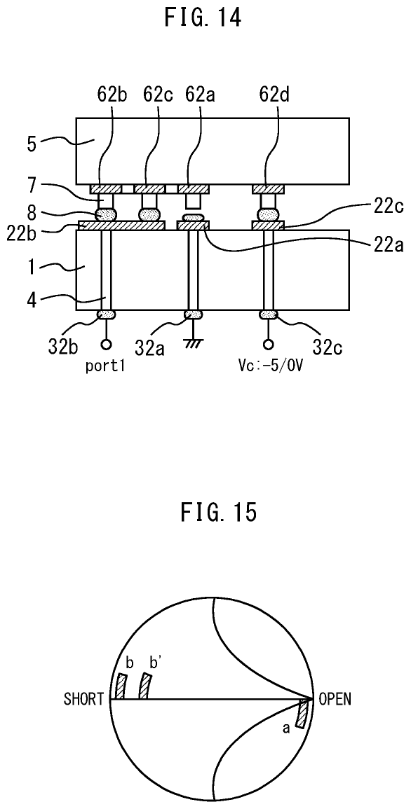

FIG. 14 is a cross-sectional view illustrating a state where the semiconductor chip according to the sixth embodiment is mounted on a multi-layer substrate by flip-chip mounting. FIG. 14 corresponds to a cross-sectional view along a line I-II in FIG. 13. As the upper-surface electrodes 2, upper-surface electrodes 22a, 22b, and 22c are formed on the upper surface of the multi-layer substrate 1. As the lower-surface electrodes 3, lower-surface electrodes 32a, 32b, and 32c are formed on the lower surface of the multi-layer substrate 1 and are respectively and individually connected with the upper-surface electrodes 22a, 22b, and 22c via the through holes 4. The pillar 7 formed on the electrode pad 62a is connected with the upper-surface electrode 22a by the solder 8. The pillars 7 formed on the inspection pads 62b and 62c are individually connected with the upper-surface electrode 22b by the solder 8. The pillar 7 formed on the control pad 62d is connected with the upper-surface electrode 22c by the solder 8. Other configurations are similar to those of the first embodiment.

In a normal action, the transistor 15 is turned on while a voltage Vc applied to the lower-surface electrode 32c is set to 0 V. In the contact check, the transistor 15 is turned off while the voltage Vc applied to the lower-surface electrode 32c is set to −5 V.

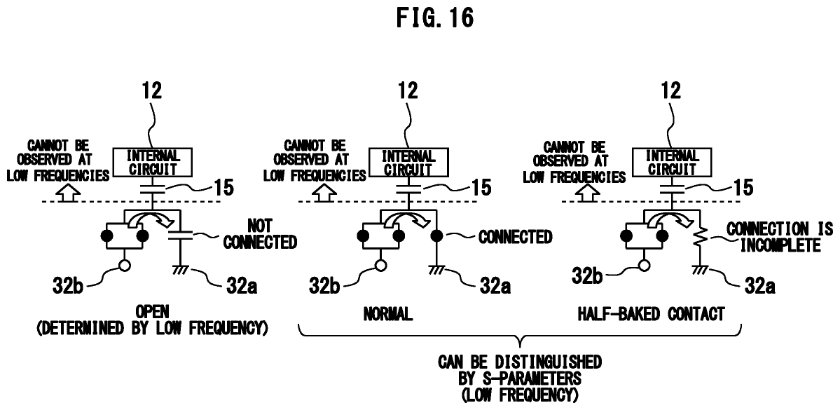

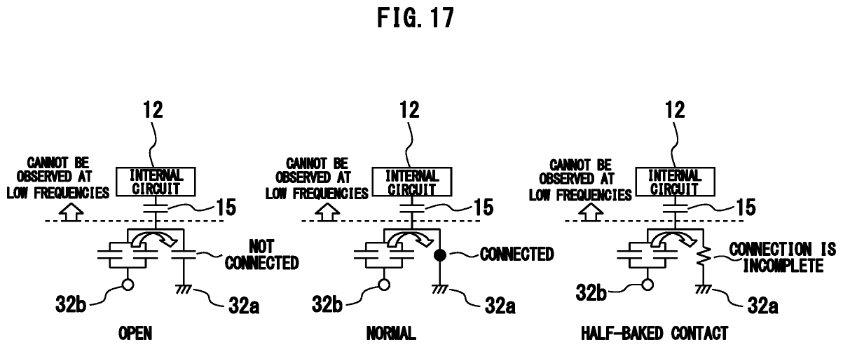

FIG. 15 is a diagram illustrating results of a measurement 1 of a semiconductor device according to the sixth embodiment. FIG. 16 and FIG. 17 are diagrams illustrating the measurement 1 of the semiconductor device according to the sixth embodiment. In the measurement 1, the lower-surface electrode 32a is grounded, the transistor 15 is turned off while the voltage Vc=−5 V is applied to the lower-surface electrode 32c, a signal is input to the lower-surface electrode 32b, and a one-port S-parameter measurement is thereby conducted. In the one-port S-parameter measurement, an amplification and a phase (S-parameter) of reflected power is measured, the reflected power being exhibited when a wave incident from the lower-surface electrode 32b is reflected to the lower-surface electrode 32b itself. In a case where a low-frequency signal at 1 GHz or lower is input, an off-capacitance of the transistor 15 and the internal circuit 12 cannot be observed. FIG. 16 illustrates a case where the inspection pads 62b and 62c are normally connected, and FIG. 17 illustrates a case where both of those are “open”.

For example, in a case where the pillar 7 of the electrode pad 62a is not connected with the upper-surface electrode 22a, the S-parameter comes to a position (a) of “open”. In a case of normal connection, the S-parameter comes to a position (b) of a short-circuit. In a case where connection is incomplete and the resistance is high, the S-parameter moves to a position (b′) on an inner side because the resistance is observed to be higher than that in the position of a short-circuit.

Note that two inspection pads 62b and 62c are provided. Thus, even when a contact defect occurs to one of the inspection pads 62b and 62c, a contact condition of the electrode pad 62a can be inspected. In a case where contact defects occur to both of the inspection pads 62b and 62c, it can also be assessed that a defect is occurring regardless of a connection condition of the electrode pad 62a.

Here, a state where connection is incomplete is a state where joining is not achieved but contact is achieved by an external force or the like. It is assumed that a contact resistance value in such a case is several ohms. For example, it is premised that the resistances of the electrode pad 62a and the inspection pads 62b and 62c are 0Ω in a case where the connection is normal and are 2Ω in a case where the connection is incomplete, and the resistance value between the lower-surface electrode 32a and the lower-surface electrode 32c is thereby measured. Relationships among contact conditions of the pads and resistance values between the electrodes are indicated in Table 1. The resistance value becomes 0 or 1Ω in cases where the contact of the electrode pad 62a is normal, and the resistance value becomes 2 or 3Ω in cases where the contact is incomplete.

TABLE 1

| Pad | Connection Condition | | | | | | | |
|---|---|---|---|---|---|---|---|---|
| 62a | Normal | Normal | Normal | Normal | Incomplete | Incomplete | Incomplete | Incomplete |
| 62b | Normal | Incomplete | Normal | Incomplete | Normal | Incomplete | Normal | Incomplete |
| 62c | Normal | Normal | Incomplete | Incomplete | Normal | Normal | Incomplete | Incomplete |
| Measured | 0 | 0 | 0 | 1 | 2 | 2 | 2 | 3 |
| Value (Ω) | | | | | | | | |

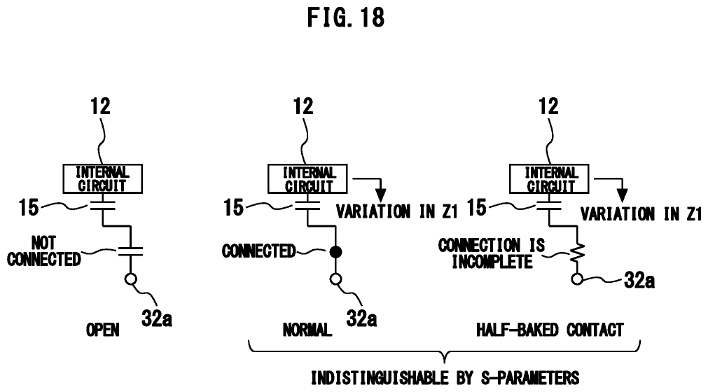

FIG. 18 is a diagram illustrating measurement according to a comparative example. In the measurement according to the comparative example, the one-port S-parameter measurement is performed directly from the lower-surface electrode 32a connected with the electrode pad 62a. In a case of normal contact, the off-capacitance of the transistor 15 can theoretically be observed, the transistor 15 being in series connected with an impedance Z1 of the internal circuit 12. However, because the impedance Z1 of the internal circuit 12 is actually non-uniform, the non-uniformity cannot be distinguished from a fluctuation in a case where the connection is incomplete. Consequently, in the comparative example, “open” in a case of a contact defect can be detected, but detection cannot be performed in a case where the connection is incomplete and the resistance is high.

In a case where the contact condition is assessed as “short” when the low-frequency signal is input in the measurement 1, it is assessed that the contact of the electrode pad 62a is normal. Otherwise, a measurement 2 is conducted. In a case where the contact condition is assessed as “open” in the measurement 2, a measurement 3 is conducted. This situation is summarized in Table 2.

TABLE 2

| Pad | Connection Condition | | | | | | | |
|---|---|---|---|---|---|---|---|---|
| 62a | Normal | Normal | Normal | Normal | open | open | open | open |
| 62b | Normal | Normal | Normal | open | Normal | open | Normal | open |
| 62c | Normal | Normal | open | open | Normal | Normal | open | open |
| Measurement | Low- | Low- | Low- | open | Characteristics | Characteristics | Characteristics | open |
| 1 | frequency | frequency | frequency | | of internal | of internal | of internal | |
| | wave | wave | wave | | circuit | circuit | circuit | |
| | short | short | short | | | | | |
| | (good) | (good) | (good) | | | | | |
| Measurement | — | — | — | open | Characteristics | Characteristics | Characteristics | open |
| 2 | | | | | of internal | of internal | of internal | |
| | | | | | circuit | circuit | circuit | |
| | | | | | (poor) | (poor) | (poor) | |
| Measurement | — | — | — | Characteristics | — | — | — | Open |
| 3 | | | | of internal | | | | (poor) |
| | | | | circuit | | | | |
| | | | | (good) | | | | |

In the measurement 2, the lower-surface electrode 32b is grounded, the transistor 15 is turned on while the voltage Vc of the lower-surface electrode 32c is set to 0 V, a high-frequency signal is input to the lower-surface electrode 32b, and the one-port S-parameter measurement is thereby conducted. When the contact of either one of the inspection pads 62b and 62c is normal, characteristics of the internal circuit 12 are measured in the measurement 2. Consequently, the S-parameter changes between the measurement 1 and the measurement 2, and “open” of the electrode pad 62a is thereby confirmed. In a case where the contact conditions of both of the inspection pads 62b and 62c are “open”, because the contact condition is measured to be “open” in the measurement 2, the measurement 3 is conducted.

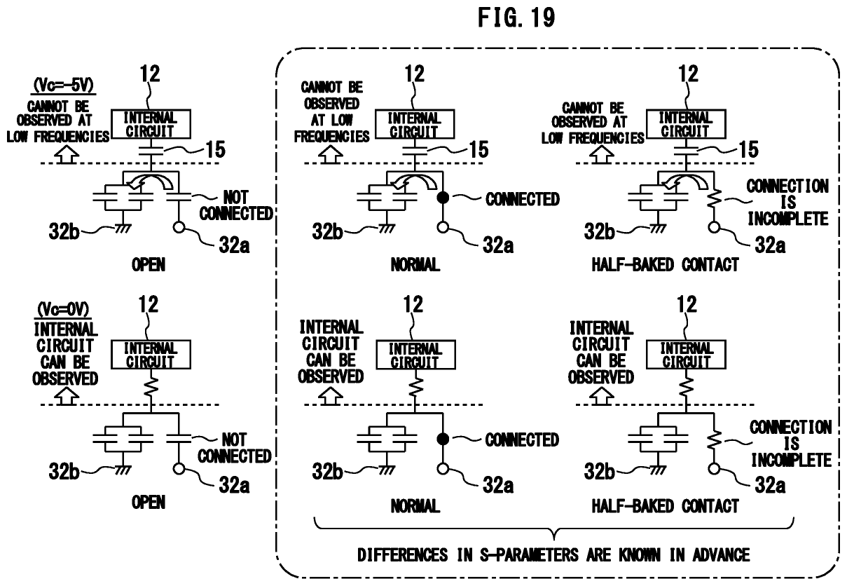

FIG. 19 is a diagram illustrating the measurement 3 of the semiconductor device according to the sixth embodiment. In the measurement 3, the lower-surface electrode 32b is grounded, the applied voltage Vc of the lower-surface electrode 32c is switched between −5 and 0 V, a high-frequency signal is input to the lower-surface electrode 32a, and the one-port S-parameter measurement is thereby conducted. In a case where the contact condition of the electrode pad 62a is “open”, the contact condition is assessed as “open” in the measurement 3.

In a case where the electrode pad 62a is connected, the characteristics of the internal circuit 12 are measured in the measurement 3. As for cases where the applied voltages Vc of the lower-surface electrode 32c are −5 V and 0 V, differences in the S-parameter between a case where the connection of the electrode pad 62a is normal and a case where the connection is incomplete are in advance recognized by experiments or simulations. Accordingly, whether the connection of the electrode pad 62a is normal or incomplete can be assessed based on measurement results of the measurement 3.

As described above, in the present embodiment, on the front surface of the semiconductor chip 5, as the pads 6, the electrode pad 62a, the inspection pads 62b and 62c, and the control pad 62d are formed. The electrode pad 62a is connected with the internal circuit 12 via the transistor 15. The inspection pads 62b and 62c are connected with the electrode pad 62a by the respective lines 13. The control pad 62d is connected with the control terminal of the transistor 15. Accordingly, a contact defect between the multi-layer substrate 1 and the semiconductor chip 5 can be detected in a non-destructive manner.

### Seventh Embodiment

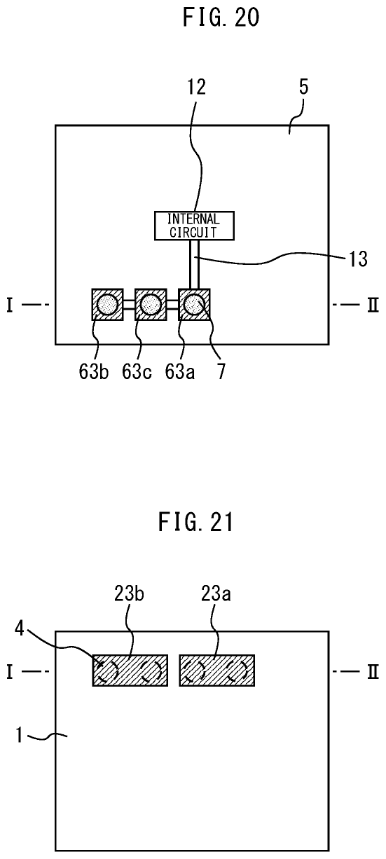

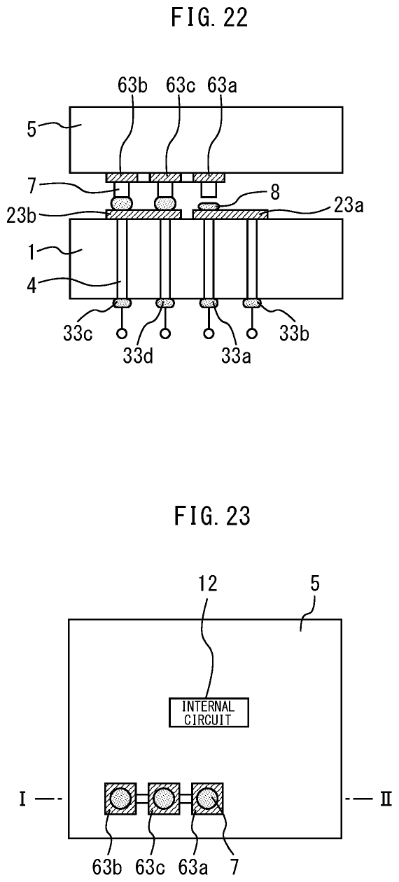

FIG. 20 is a diagram illustrating a front surface of a semiconductor chip according to a seventh embodiment. FIG. 21 is a diagram illustrating an upper surface of a multi-layer substrate according to the seventh embodiment. FIG. 22 is a cross-sectional view illustrating a state where the semiconductor chip according to the seventh embodiment is mounted on the multi-layer substrate by flip-chip mounting. FIG. 22 corresponds to a cross-sectional view along lines I-II in FIG. 20 and FIG. 21.

On the front surface of the semiconductor chip 5, as the pads 6, a pad 63a and pads 63b and 63c, which are connected with the pad 63a by the line 13, are formed. The pad 63a is a DC supplying pad or an RF electrode pad which is connected with the internal circuit 12.

On the upper surface of the multi-layer substrate 1, as the upper-surface electrodes 2, an upper-surface electrode 23a and an upper-surface electrode 23b are formed, the upper-surface electrode 23a being connected with the pillar 7 formed on the pad 63a by the solder 8, the upper-surface electrode 23b being individually connected with the pillars 7 formed on the pads 63b and 63c by the solder 8.

On the lower surface of the multi-layer substrate 1, as the lower-surface electrodes 3, lower-surface electrodes 33a and 33b and lower-surface electrodes 33c and 33d are formed, the lower-surface electrodes 33a and 33b being individually connected with the upper-surface electrode 23a by the through holes 4, the lower-surface electrodes 33c and 33d being individually connected with the upper-surface electrode 23b by the through holes 4. Other configurations are similar to those of the first embodiment.

For example, a four-terminal resistance measurement is conducted by using the lower-surface electrodes 33c and 33b on an outer side as force terminal through which a current flow and by using the lower-surface electrodes 33a and 33d on an inner side as sensing terminals for measuring a voltage. The contact condition becomes “open” in a case of a contact defect and becomes “short” in a case of normal contact. Thus, a contact defect between the multi-layer substrate 1 and the semiconductor chip 5 can be detected in a non-destructive manner.

Because a difference in the resistance value between a case where solder connection of the pads is normal and a case where the solder connection is incomplete is insignificant, a contact resistance between an inspection apparatus and the lower-surface electrode disturbs an inspection. However, because no current flows through the sensing terminals, the contact resistance can be ignored. Thus, whether the connection is normal or incomplete can be discriminated by figuring out the difference in the resistance value between both of those cases.

### Eighth Embodiment

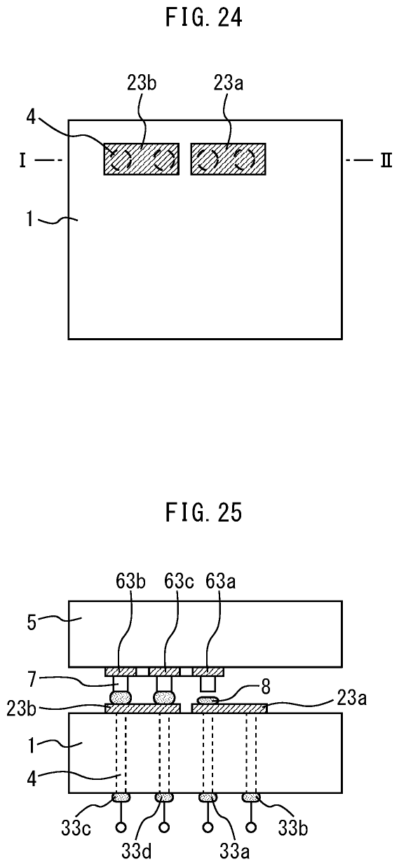

FIG. 23 is a diagram illustrating a front surface of a semiconductor chip according to an eighth embodiment. FIG. 24 is a diagram illustrating an upper surface of a multi-layer substrate according to the eighth embodiment. FIG. 25 is a cross-sectional view illustrating a state where the semiconductor chip according to the eighth embodiment is mounted on the multi-layer substrate by flip-chip mounting. FIG. 25 corresponds to a cross-sectional view along a line I-II in FIG. 23 and FIG. 24.

As for a point different from the seventh embodiment, the pads 63a, 63b, and 63c are inspection pads which are not connected with the internal circuit 12 and are formed in at least three parts in the four corners on the front surface of the semiconductor chip 5. Other configurations are similar to those of the first and seventh embodiments.

A check is made about whether an opening or a short-circuit is occurring in the contacting part of the inspection pad in each of the parts. In a case where short-circuits are occurring in all of the contacting parts, it can be determined that the semiconductor chip 5 is evenly mounted. In this case, it can be determined that electrode pads are also in contact. Thus, a contact defect between the multi-layer substrate 1 and the semiconductor chip 5 can be detected in a non-destructive manner. Note that the pads 63a, 63b, and 63c may be formed in four corners on the front surface of the semiconductor chip 5 or may be formed in central portions of the semiconductor chip 5.

Although the preferred embodiments and the like have been described in detail above, the present disclosure is not limited to the above-described embodiments and the like, but the above-described embodiments and the like can be subjected to various modifications and replacements without departing from the scope described in the claims. Aspects of the present disclosure will be collectively described as supplementary notes.

### Supplementary Note 1

A semiconductor device comprising:
a multi-layer substrate; and
a semiconductor chip mounted on the multi-layer substrate by flip-chip mounting and having an internal circuit,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder,
the plural pads include an electrode pad connected with the internal circuit and plural inspection pads formed in at least three parts in four corners on the front surface of the semiconductor chip and not connected with the internal circuit, and
a line connects the adjacent inspection pads with each other.

### Supplementary Note 2

The semiconductor device according to Supplementary Note 1, wherein the plural inspection pads include first to fourth inspection pads formed in four corners on the front surface of the semiconductor chip.

### Supplementary Note 3

The semiconductor device according to Supplementary Note 1 or 2, wherein the plural inspection pads include a fifth inspection pad formed in a central portion of the front surface of the semiconductor chip.

### Supplementary Note 4

The semiconductor device according to any one of Supplementary Notes 1 to 3, wherein a resistance is connected between the adjacent inspection pads.

### Supplementary Note 5

The semiconductor device according to Supplementary Note 2, further comprising a printed substrate on which the multi-layer substrate is mounted,
wherein the line is formed along an outer circumference of the front surface of the semiconductor chip, and
the lower-surface electrode connected to any one of the plural inspection pads is connected to a GND terminal of the printed substrate.

### Supplementary Note 6

A semiconductor device comprising:
a multi-layer substrate; and
a semiconductor chip mounted on the multi-layer substrate by flip-chip mounting and having an internal circuit and a transistor,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder, and
the plural pads include an electrode pad connected with the internal circuit via the transistor, an inspection pad connected with the electrode pad, and a control pad connected with a control terminal of the transistor.

### Supplementary Note 7

A semiconductor device comprising:
a multi-layer substrate; and
a semiconductor chip mounted on the multi-layer substrate by flip-chip mounting,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder,
the plural pads include a first pad and a second pad connected with the first pad,
the plural upper-surface electrodes include a first upper-surface electrode connected with the pillar formed on the first electrode pad by the solder and a second upper-surface electrode connected with the pillar formed on the second electrode pad by the solder, and
the plural lower-surface electrodes include first and second lower-surface electrodes individually connected with the first upper-surface electrode and third and fourth lower-surface electrodes individually connected with the second upper-surface electrode.

### Supplementary Note 8

The semiconductor device according to Supplementary Note 7, wherein the semiconductor chip has an internal circuit, and
the first pad is connected with the internal circuit.

### Supplementary Note 9

The semiconductor device according to Supplementary Note 7, wherein the semiconductor chip has an internal circuit, and
the first and second pads are not connected with the internal circuit and formed in at least three parts in four corners on the front surface of the semiconductor chip.

### Supplementary Note 10

The semiconductor device according to Supplementary Note 9, wherein the first and second pads are formed in the four corners on the front surface of the semiconductor chip.

### Supplementary Note 11

The semiconductor device according to Supplementary Note 9 or 10, wherein the first and second pads are formed in a central portion of the front surface of the semiconductor chip.

### Supplementary Note 12

The semiconductor device according to any one of Supplementary Notes 1 to 11, comprising a heat sink die-bonded to a back surface of the semiconductor chip, and a mold resin sealing the multi-layer substrate, the semiconductor chip, and the heat sink,
wherein an upper surface of the heat sink is exposed from the mold resin.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2023-064244, filed on Apr. 11, 2023 including specification, claims, drawings and summary, on which the convention priority of the present application is based, is incorporated herein by reference in its entirety.

1. A semiconductor device comprising:
a multi-layer substrate; and
a semiconductor chip mounted on the multi-layer substrate by flip-chip mounting and having an internal circuit,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder,
the plural pads include an electrode pad connected with the internal circuit and plural inspection pads formed in at least three parts in four corners on the front surface of the semiconductor chip and not connected with the internal circuit, and
a line connects the adjacent inspection pads with each other.

2. The semiconductor device according to claim 1, wherein the plural inspection pads include first to fourth inspection pads formed in four corners on the front surface of the semiconductor chip.

3. The semiconductor device according to claim 1, wherein the plural inspection pads include a fifth inspection pad formed in a central portion of the front surface of the semiconductor chip.

4. The semiconductor device according to claim 1, wherein a resistance is connected between the adjacent inspection pads.

5. The semiconductor device according to claim 2, further comprising a printed substrate on which the multi-layer substrate is mounted,
wherein the line is formed along an outer circumference of the front surface of the semiconductor chip, and
the lower-surface electrode connected to any one of the plural inspection pads is connected to a GND terminal of the printed substrate.

6. The semiconductor device according to claim 1, comprising a heat sink die-bonded to a back surface of the semiconductor chip, and a mold resin sealing the multi-layer substrate, the semiconductor chip, and the heat sink,
wherein an upper surface of the heat sink is exposed from the mold resin.

7. A semiconductor device comprising:
a multi-layer substrate; and
a semiconductor chip mounted on the multi-layer substrate by flip-chip mounting and having an internal circuit and a transistor,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder, and
the plural pads include an electrode pad connected with the internal circuit via the transistor, an inspection pad connected with the electrode pad, and a control pad connected with a control terminal of the transistor.

8. The semiconductor device according to claim 7, comprising a heat sink die-bonded to a back surface of the semiconductor chip, and a mold resin sealing the multi-layer substrate, the semiconductor chip, and the heat sink,
wherein an upper surface of the heat sink is exposed from the mold resin.

9. A semiconductor device comprising:
a multi-layer substrate; and
a semiconductor chip mounted on the multi-layer substrate by flip-chip mounting,
wherein plural pads are formed on a front surface of the semiconductor chip,
plural pillars are respectively formed on the plural pads,
plural upper-surface electrodes are formed on an upper surface of the multi-layer substrate,
plural lower-surface electrodes are formed on a lower surface of the multi-layer substrate and are respectively connected with the plural upper-surface electrodes via through holes,
the plural pillars are joined to the plural upper-surface electrodes by solder,
the plural pads include a first pad and a second pad connected with the first pad,
the plural upper-surface electrodes include a first upper-surface electrode connected with the pillar formed on the first electrode pad by the solder and a second upper-surface electrode connected with the pillar formed on the second electrode pad by the solder, and
the plural lower-surface electrodes include first and second lower-surface electrodes individually connected with the first upper-surface electrode and third and fourth lower-surface electrodes individually connected with the second upper-surface electrode.

10. The semiconductor device according to claim 9, wherein the semiconductor chip has an internal circuit, and
the first pad is connected with the internal circuit.

11. The semiconductor device according to claim 9, wherein the semiconductor chip has an internal circuit, and
the first and second pads are not connected with the internal circuit and formed in at least three parts in four corners on the front surface of the semiconductor chip.

12. The semiconductor device according to claim 11, wherein the first and second pads are formed in the four corners on the front surface of the semiconductor chip.

13. The semiconductor device according to claim 11, wherein the first and second pads are formed in a central portion of the front surface of the semiconductor chip.

14. The semiconductor device according to claim 9, comprising a heat sink die-bonded to a back surface of the semiconductor chip, and a mold resin sealing the multi-layer substrate, the semiconductor chip, and the heat sink,
wherein an upper surface of the heat sink is exposed from the mold resin.
